(19) United States
(12) Patent Application Publication
(10) Pub. No.: US 2016/0342463 A1
(43) Pub. Date: Nov. 24, 2016

(54) DATA PROTECTION IN A NAMESPACE

(71) Applicant: KABUSHIKI KAISHA TOSHIBA, Tokyo (JP)

(72) Inventor: Gen OSHIMA, Mountain View, CA (US)

(21) Appl. No.: 14/717,658

(22) Filed: May 20, 2015

(51) Int. Cl. G06F 11/10; G11C 29/52; G06F 3/06

(52) U.S. Cl. CPC G06F 11/1004; G06F 3/0688; G06F 3/0655; G06F 3/061; G06F 3/0619; G06F 11/1068; G11C 29/52

(57) ABSTRACT

Techniques for managing addresses for a non-volatile semiconductor storage device. The techniques include a method that includes determining an error-correction seed for data for a non-volatile semiconductor storage device based on a first logical address associated with the data that includes a first namespace identifier and a first logical block address. The method also includes converting the first logical address to an internal linear address that does not include the first namespace identifier. The method further includes determining a physical address based on the internal linear address. The method also includes accessing data stored in the non-volatile semiconductor storage device based on the physical address. A storage device and non-transitory computer readable medium are also provided.

### BACKGROUND

Solid-state drives (SSDs) generally have faster performance, are more compact, and are less sensitive to vibration or physical shock than conventional magnetic disk drives. Given these advantages, SSDs are being used in more and more computing devices and other consumer products in lieu of or in addition to magnetic disk drives, even though the cost-per-gigabyte storage capacity of SSDs is significantly higher than that of magnetic disk drives.

For various reasons, writing data to and reading data from the physical memory cells of SSDs is not straightforward and typically involves shuffling data between various memory cells. Despite this data shuffling, SSDs are able to present consistent, unchanging memory addresses to host systems by using logical-to-physical address translation mechanisms. Hosts use logical addresses, rather than physical addresses, to access data stored in the SSD. The translation mechanisms effectively obscure the shuffling and management of the memory cells so that a host system does not need to account for such operations.

In addition to logical-to-physical address translation, various other operations in SSDs manipulate or otherwise utilize logical address. For example, techniques such as wear leveling and garbage collection utilize logical addresses.

A relatively recent standard for accessing data stored in SSDs—the NVMe (“non-volatile memory express”) standard—specifies that data stored in an SSD may be logically divided into resizable chunks referred to as namespaces. A logical address for accessing SSDs that implement namespaces includes a namespace identifier as well as an address within that namespace. Because such addresses include two independent values they have a more complicated format than addresses that do not include namespaces. Because of this complexity, what is needed in the art are techniques for managing and utilizing logical addresses that include or are derived from namespaces.

### SUMMARY

One embodiment disclosed herein includes a data storage device. The data storage device includes a non-volatile semiconductor storage device and a controller. The controller is configured to determine an error-correction seed for data for the non-volatile semiconductor storage device based on a first logical address associated with the data that includes a first namespace identifier and a first logical block address. The controller is also configured to convert the first logical address to an internal linear address that does not include the first namespace identifier. The controller is further configured to determine a physical address based on the internal linear address. The controller is also configured to access data stored in the non-volatile semiconductor storage device based on the physical address.

One embodiment disclosed herein includes a method that includes determining an error-correction seed for data for a non-volatile semiconductor storage device based on a first logical address associated with the data that includes a first namespace identifier and a first logical block address. The method also includes converting the first logical address to an internal linear address that does not include the first namespace identifier. The method further includes determining a physical address based on the internal linear address. The method also includes accessing data stored in the non-volatile semiconductor storage device based on the physical address.

One embodiment disclosed herein provides A non-transitory computer readable medium. The non-transitory computer-readable medium stores instructions that, when executed by a processor, cause the processor to perform a method. The method includes determining an error-correction seed for data for a non-volatile semiconductor storage device based on a first logical address associated with the data that includes a first namespace identifier and a first logical block address. The method also includes converting the first logical address to an internal linear address that does not include the first namespace identifier. The method further includes determining a physical address based on the internal linear address. The method also includes accessing data stored in the non-volatile semiconductor storage device based on the physical address.

### BRIEF DESCRIPTION OF THE DRAWINGS

FIG. 1 is a block diagram of a solid-state drive (SSD), configured according to one or more embodiments.

FIG. 2 is a diagram that illustrates namespace-based logical addressing, according to an example.

FIG. 3 illustrates a technique for converting namespace-based addresses to linear, internal addresses.

FIG. 4 is a block diagram that illustrates operations associated with resizing namespaces, according to an example.

FIG. 5 illustrates the different addressing spaces and the functions with which they are associated.

FIG. 6 is a processing flow diagram that shows addresses as manipulated by an SSD controller, according to an example.

FIG. 7 is a flow diagram of method steps for managing namespace-based logical addresses, according to an example.

### DETAILED DESCRIPTION

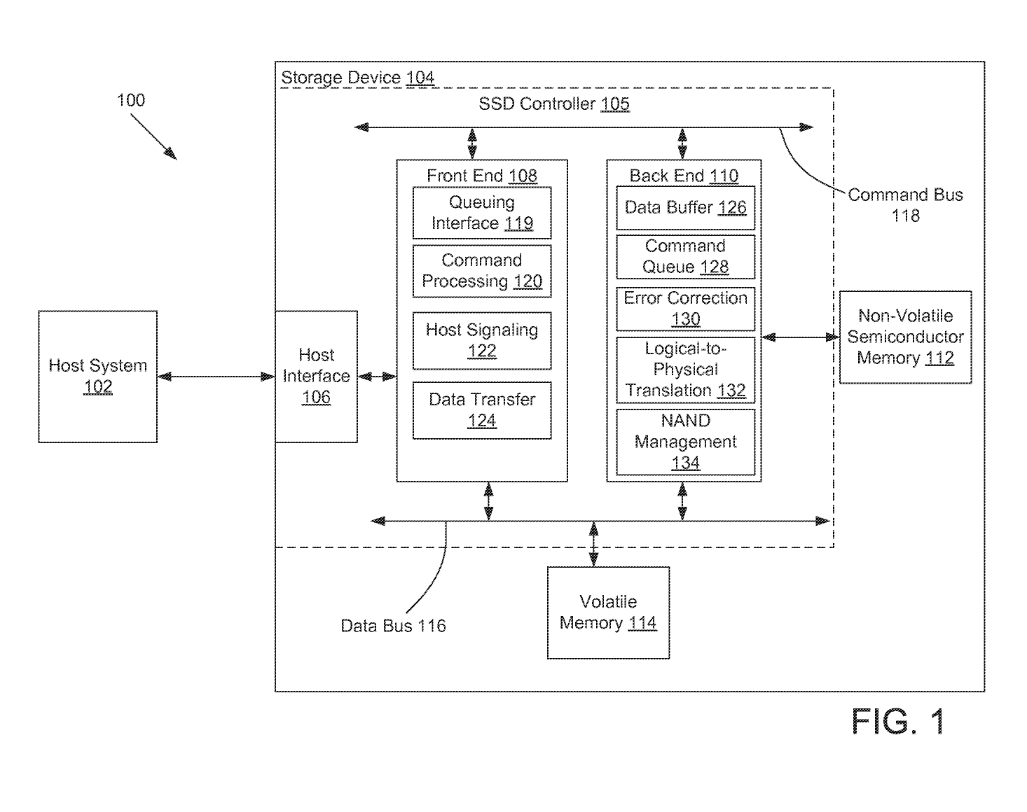

FIG. 1 is a block diagram of a computing system 100 including a storage device 104 in communication with a host system 102. Host system 102 is a computing system that comprises processors, memory, and other components as is generally known. Storage device 104 provides non-volatile storage functionality for use by host system 102. Storage device 104 is a solid-state drive (“SSD”), which is a non-volatile storage device that includes non-volatile semiconductor-based storage elements, such as NAND-based flash memory, as the storage medium (as opposed to, for example, the magnetic medium used in hard disk drives).

Storage device 104 includes an SSD controller 105, volatile memory 114, and non-volatile semiconductor memory 112. Storage device 104 may also include other elements not shown, such as power supply circuitry (including circuitry for transferring power to the SSD controller 105, volatile memory 114, and non-volatile semiconductor memory 112 as well as capacitors for buffering the power supply), indicator light circuitry, temperature sensors, boot circuitry, clock circuitry, and other circuitry for assisting with various functions.

SSD controller 105 receives and processes commands from host system 102 in order to perform operations on the non-volatile semiconductor memory 112. Commands from host system 102 include requests to read or write to locations within the non-volatile semiconductor memory 112, and various administrative commands, such as commands for querying the feature set of storage device 104, commands for formatting non-volatile memory 112, commands for creating and modifying various types of queues, commands for requesting notification of various events, and various other commands. SSD controller 105 includes a host interface 106, a front end 108, a back end 110, a command bus 118, and a data bus 116.

Host interface 106 comprises circuitry for communicating with host system 102. In one embodiment, the interface with which host system 102 communicates with host interface 106 is a peripheral component interconnect express (“PCIe”) interface that communicates according to the PCIe standard. In another embodiment, the interface is a serial advanced technology attachment (SATA) interface.

Front end 108 communicates with host system 102 to receive, organize, and forward commands and data from host system 102 to back end 110, and communicates with back end 110 to forward data from back end 110 to host system 102. Back end 110 performs tasks associated with commands received from front end 108, accessing non-volatile semiconductor memory 112 as needed in accordance with these tasks.

Both front end 108 and back end 110 are coupled to a command bus 118 and a data bus 116. Command bus 118 functions to transfer command-related data between various sub-units of front end 108 and back end 110, and data bus 116 serves to transfer data that is read from non-volatile semiconductor memory 112 (“read data”) and data that is written to non-volatile semiconductor memory 112 (“write data”) between various sub-units of front end 108 and back end 110. Data bus 116 is also coupled to volatile memory 114. Thus, both front end 108 and back end 110 can access volatile memory 114.

Non-volatile semiconductor memory 112 stores data in a non-volatile manner at the request of host system 102. Non-volatile semiconductor memory 112 includes one or more arrays of non-volatile semiconductor-based storage elements, some examples of which include non-volatile NAND flash memory, non-volatile NOR flash memory, non-volatile DRAM based memory, magnetoresistive random-access memory (MRAM), and other types of memory. As NAND-based flash memory is commonly used as the non-volatile semiconductor memory 112, non-volatile semiconductor memory 112 may be referred to herein as NAND memory 112 or simply as NAND 112.

Front end 108 includes multiple functional units, including queuing interface 119, command processing unit 120, host signaling unit 122, and data transfer unit 124. Queuing interface 119 communicates with host system 102 about the status of commands stored in submission queues and completion queues stored in memory within host system 102. Submission queues store commands to be fetched by SSD controller 105 and completion queues store information about commands completed by SSD controller 105. Command processing unit 120 forwards received commands to back end 110 for processing. Command processing unit 120 may also include a command arbitrator that selects one or more commands to forward to back end 110 for processing based on an arbitration schedule or technique.

Host signaling unit 122 generates host notification signals and transmits these signals to host system 102. These signals may be used to indicate that one or more commands submitted by host system 102 are complete. Host notification signals include interrupts and may be out-of-band, pin-based interrupts, or may be in-band message signaled interrupts (“MSI” or “MSIx”). The interrupts include data identifying the command that has been completed as well as status data associated with that command. Host signaling unit 122 includes an interrupt table that includes such information, as well as an interrupt generator which generates interrupts for transmission to host system 102, based on the information stored in the interrupt table.

Data transfer unit 124 serves as an intermediary between host interface 106 and back end 110. Data transfer unit 124 directs data received from host interface 106 to be stored in volatile memory 114 for later retrieval at the direction of back end 110. Data transfer unit also directs data stored in volatile memory 114 at the direction of back end for later transmission to host system 102 via host interface 106.

Back end 110 includes multiple functional units, including a data buffer 126, a command queue 128, an error correction unit 130, a logical-to-physical address translation unit 132, and a NAND management unit 134. Data buffer 126 configures a read cache and a write cache in volatile memory 114. A read cache temporarily stores data read from non-volatile semiconductor memory 112 in response to a command from host system 102, for transmission by front end 108 to host system 102 through host interface 106. A write cache temporarily stores data received from host system 102 and transmitted by front end 108, to be written to non-volatile semiconductor memory 112.

Command queue 128 stores commands received from front end 108 for further processing. Buffering commands in this manner allows back end 110 to process received commands based on a particular schedule or on specific timing or state-based constraints.

Error correction unit 130 provides error correction functionality for data stored in non-volatile semiconductor memory 112. Error correction unit 130 generates error-correction data for data written to the non-volatile semiconductor memory 112 and stores the error-correction data with the written data. When the written data is read out and error in reading is encountered, error correction unit 130 performs error correction operations using the error-correction data.

Logical-to-physical translation unit 132 translates logical addresses, e.g., logical block addresses (LBAs), to physical addresses, e.g., physical block addresses, of non-volatile semiconductor memory 112 during reading or writing data. Logical-to-physical translation unit 132 accesses a map, known as a flash translation layer (FTL), when converting logical addresses to physical addresses so that data requested by host system 102 with a logical address can be properly physically addressed within non-volatile semiconductor memory 112.

NAND management unit 134 may provide wear leveling, bad block mapping, garbage collection, and read scrubbing.

Wear leveling is a technique to compensate for the fact that a (relatively) limited number of write operations can be performed on each NAND data storage element, commonly referred to as a block. Wear leveling comprises periodically moving data between NAND data storage blocks in order to even out or “level” the number of times write operations are performed for each data storage block. Bad block mapping is a technique for marking blocks as being “bad” after it is discovered that such blocks are unreliable. Blocks marked as bad are not written to or read from.

Garbage collection is a technique whereby valid pages (a subunit of a block) within a block are copied to a new block so that the source block can be erased. Garbage collection is needed in NAND memory because the unit of writing is a page and the unit of erasure is a block. Accordingly, if a command to write data targets an existing page, then the data of the existing page is not actually modified. Instead, a new page is written and the old page is marked as invalid. As a result, the number of invalid pages continue to grow and garbage collection becomes necessary to free up blocks having a large number of invalid pages.

Read scrubbing is a technique whereby SSD controller 105 periodically reads data in the non-volatile semiconductor memory 112, performs error checking operations on the data to determine if there are errors, corrects errors that are found, and then writes the error-corrected data back to the same location. This technique helps to reduce the amount of errors experienced when reading data out from the non-volatile semiconductor memory 112.

In various embodiments, the functional blocks included in front end 108 and back end 110 represent hardware or combined software and hardware elements for performing associated functionality. Thus, any or all of the functional blocks may be embodied as firmware executing in a processing unit, as hardware units that are hard-wired to perform the associated functionality, or as a combination thereof. For example, either or both of front end 108 or back end 110 may include one or more processors, one or more state machines, one or more application specific integrated circuits (ASICs), or the like, that are programmed or configured to perform functions related to the functional blocks. Alternatively, a single processor may be shared between and thus may perform the functions of both front end 108 and back end 110.

Certain functional blocks and functionality associated therewith that are depicted as being included within front end 108 or back end 110 may be implemented as data structures stored within volatile memory 114. Thus, for example, queues indicated as being included in front end 108 and back end 110, may be stored within volatile memory 114.

For purposes of illustration, both an example read operation and an example write operation are now described. To write data to NAND 112, host system 102 provides a write command, write data, and a logical address to front end 108 via host interface 106. Command processing unit 120 of front end 108 receives this command and forwards the command to command queue 128 of back end 110 for processing. Data transfer unit 124 of front end 108 forwards the data to the write cache of back end 110 configured in volatile memory 114. Logical-to-physical translation unit 132 converts the logical address received to a physical address. NAND management unit 134 performs any associated techniques on NAND 112, such as generating error-correction data and back end 110 writes the specified data to NAND 112. After this command is complete, back end 110 signals front end 108, which generates a completion signal (such as an interrupt) and transmits that signal to host system 102, indicating that the write command has been completed.

To read data from NAND 112, host system 102 provides a read command and a logical address to front end 108 via host interface 106. Command processing unit 120 of front end 108 receives this command and forwards the command to command queue 128 of back end 110 for processing. Logical-to-physical translation unit 132 translates the logical address to a physical address and provides the physical address to NAND 112 for reading. NAND 112 returns the requested data. Error correction 130 performs error correcting operations on the data. Back end 110 stores the data in the read cache configured in volatile memory 114 and indicates to front end 108 that the command is complete. Host signaling unit 122 generates a completion signal and transmits that signal to the host system 102, along with the data read from NAND 112.

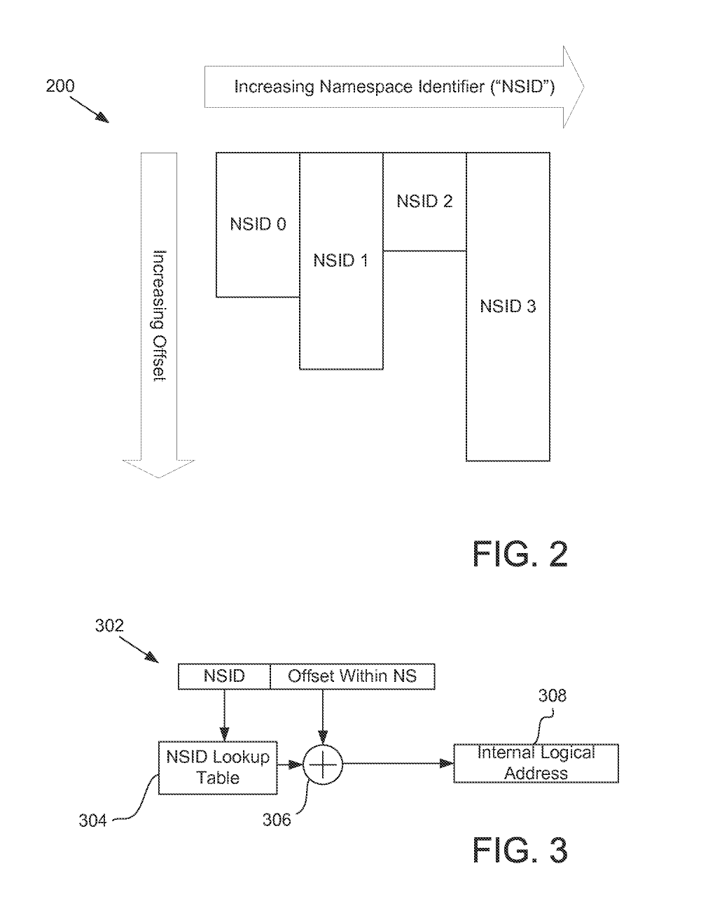

FIG. 2 is a diagram 200 that illustrates namespace-based logical addressing, according to an example. Namespaces are a feature specified in the NVMe standard. NVMe (NVMe is an acronym for “NVM express,” where “NVM” stands for “non-volatile memory”) is a standard for accessing solid state drives (SSDs) through a PCIe (“Peripheral Component Interface Express”) bus. NVMe is also known in the industry as NVMHCI, which is an acronym for “Non-Volatile Memory Host Controller Interface.”

Among other features, NVMe specifies that data stored in an SSD may be logically organized into subdivisions referred to as namespaces. The use of namespaces means that logical addresses provided by host system 102 to SSD controller 105 include a namespace identifier, which identifies a namespace (and can be, for example, a short sequence of bits), in addition to a logical block address, which identifies a logical block within that namespace.

The diagram 200 illustrated in FIG. 2 graphically illustrates an address space associated with namespace-based addressing. As shown, an address in the address space includes a namespace identifier (“NSID”) and a logical address within the namespace (also referred to as an offset or an offset within the namespace). Within each namespace, logical addresses begin at zero and increase linearly. Namespaces may be resized on demand.

One issue with namespace-based addresses is that they are not amenable for use as an index to a lookup table for converting logical addresses to physical addresses. More specifically, as described above in conjunction with FIG. 1, logical-to-physical translation unit 132 uses a lookup table in order to obtain a physical address based on a logical address. For efficiency, it is advantageous for logical-to-physical translation unit 132 to use a logical address as an index to a single lookup table that encompasses all namespaces managed by SSD controller 105. However, the namespace-based addresses illustrated in FIG. 2 are not amenable for use in such a table. More specifically, a single table is efficiently indexed by a single set of numbers that linearly increase from a lowest value to a highest value. The namespace-based address space does not include such a single set of linearly increasing numbers. Instead, the namespace-based address space includes multiple sets of numbers that each begin at zero and then linearly increase, as the offsets in each namespace begin at zero. Thus, for namespace-based addresses, either some form of address manipulation or multiple tables would be required, which would increase the number of operations to perform when a logical-to-physical conversion is needed. For these reasons, utilizing a namespace-based address as an index to a lookup table would be cumbersome.

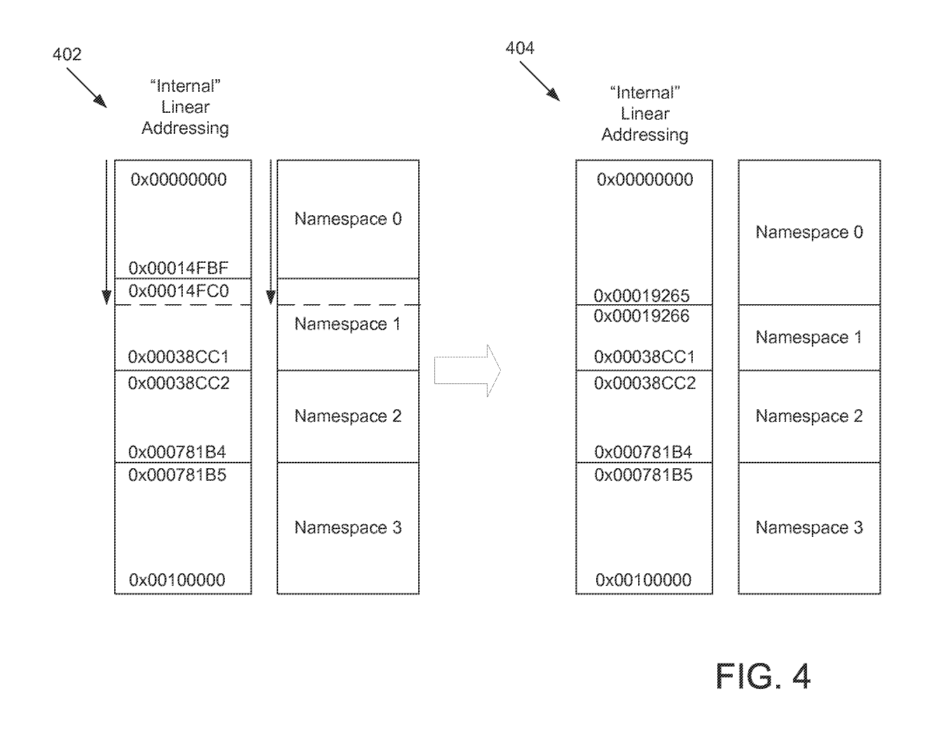

Thus, instead of using namespace-based addresses as indexes to logical-to-physical lookup tables, logical-to-physical translation unit 132 instead first converts the namespace-based address to a linear, internal address that is not based on namespaces (also referred to herein simply as an “internal address,” or a “linear address”) and uses that linear, internal address as an index to a logical-to-physical lookup table. Within the linear address space that is associated with the linear, internal address, the namespaces are arrayed in a back-to-back manner, so that the linear addresses corresponding to one namespace are adjacent to the linear addresses corresponding to the subsequent namespace. This effectively converts the namespace-based address space into an address space that includes a single set of numbers that begin at 0 and increase to a maximum number. The correspondence between namespace-based addresses and the internal, linear addresses is discussed in greater detail below with respect to FIGS. 3 and 4. Use of these linear addresses allows for efficient indexing of a logical-to-physical conversion table.

Note that the term “logical block address” may also be referred to herein as an “offset.” The term “offset” may also be used to specify a particular subdivision of a namespace that has a different size than a block. For example, an offset may specify the location of a “segment,” which has a size less than or equal to the size of a block or the location of a “cluster” which has a size less than or equal to the size of a segment.

FIG. 3 illustrates a technique for converting namespace-based addresses to linear, internal addresses. These addresses are referred to as “internal” because while SSD controller 105 uses such addresses, these addresses are not visible to host system 102, which instead uses the namespace-based addresses to access data stored in NAND 112.

The linear, internal address space is more amenable to being used as an index to a logical-to-physical address lookup table. More specifically, because the internal addresses are linear, that is, strictly increasing from a lowest address (e.g., 0) to a maximum address, these numbers properly line up with a table structure. Thus no manipulation of the type associated with namespace-based addresses would be required.

Use of linear addresses also provides a convenient mechanism for resizing namespaces. More specifically, storage device 104 correlates each namespace with a particular subdivision of the linear address space. Thus, namespaces can be defined as a beginning linear address and an end linear address. To resize a namespace, SSD controller 105 simply changes the range of linear addresses associated with that namespace.

Converting namespace-based addresses to linear addresses is performed as follows. Logical-to-physical translation unit 132 provides the namespace ID (“NSID”) portion of a namespace-based address 302 to a NSID lookup table 304, which converts NSIDs to base addresses in the linear, internal address space. A base address is simply the beginning address of the corresponding namespace, within the linear address space. An adder 306 of logical-to-physical translation unit 132 adds the base address to the offset portion of address 302 to arrive at the linear, internal address 308.

FIG. 4 is a block diagram that illustrates operations associated with resizing namespaces, according to an example. As shown, FIG. 4 illustrates a first namespace state 402 in which namespace 0 and namespace 1 have respective original sizes and a second namespace state 404 in which namespace 0 and namespace 1 have respective new sizes.

More specifically, in the second namespace state 404, the size of namespace 0 has been increased and the size of namespace 1 has been decreased. To resize namespace 0, SSD controller 105 changes the end address associated with the namespace to a higher address in the linear address space. Similarly, to resize namespace 1, SSD controller 105 changes the beginning address associated with that namespace to a higher linear address. SSD controller 105 may also change mappings in a logical-to-physical mapping table in order to accommodate the changed addresses associated with the resized namespaces. It can be seen that by mapping namespace addresses to linear, internal addresses as shown, resizing operations are relatively easy to complete. Moreover, converting namespace-based logical addresses to the internal, linear addresses is relatively simple as well, as described above with respect to FIG. 3.

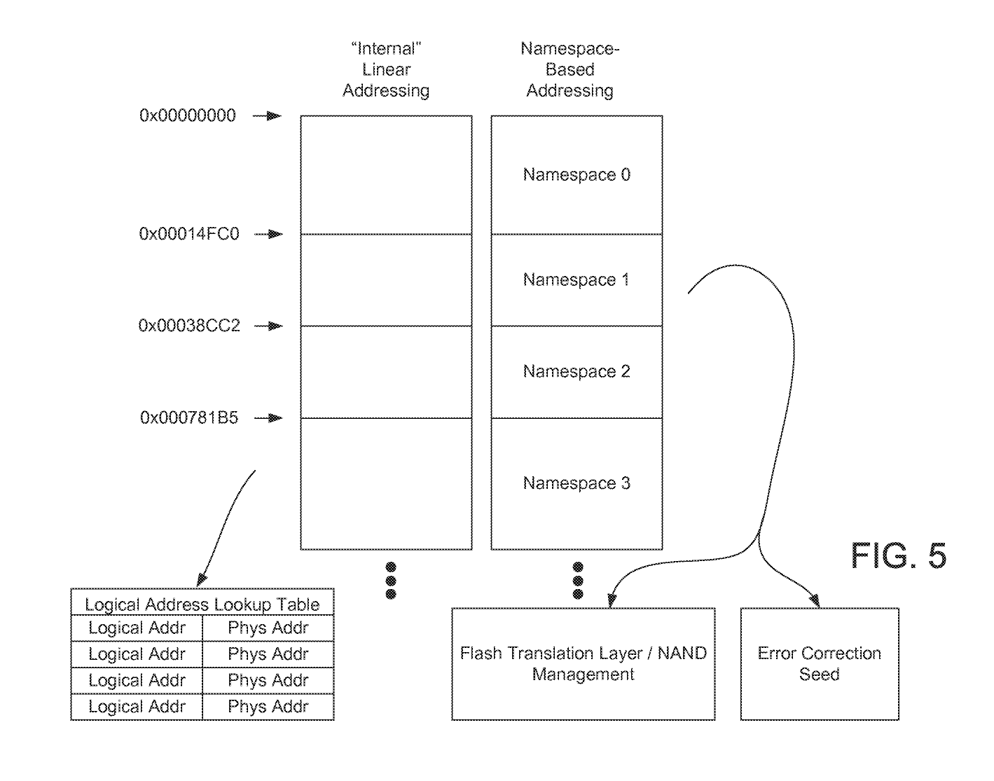

Although these linear addresses are advantageously used to index a logical-to-physical mapping table, they are not advantageously used for other functionality of SSD controller 105. FIG. 5 illustrates different addressing spaces (linear and namespace-based) and the functions with which they are associated.

For example, it is advantageous to use linear addressing as an index to a logical-to-physical mapping table, and it is advantageous to use the namespace-based addresses for both cyclic redundancy check (“CRC”) seeds as well as for other internal operations associated with the flash transfer layer (“FTL”). Thus, FIG. 5 illustrates that linear addresses are used for the lookup while namespace-based addresses are used for both cyclic redundancy check (“CRC”) seeds as well as for other internal operations associated with the flash transfer layer (“FTL”).

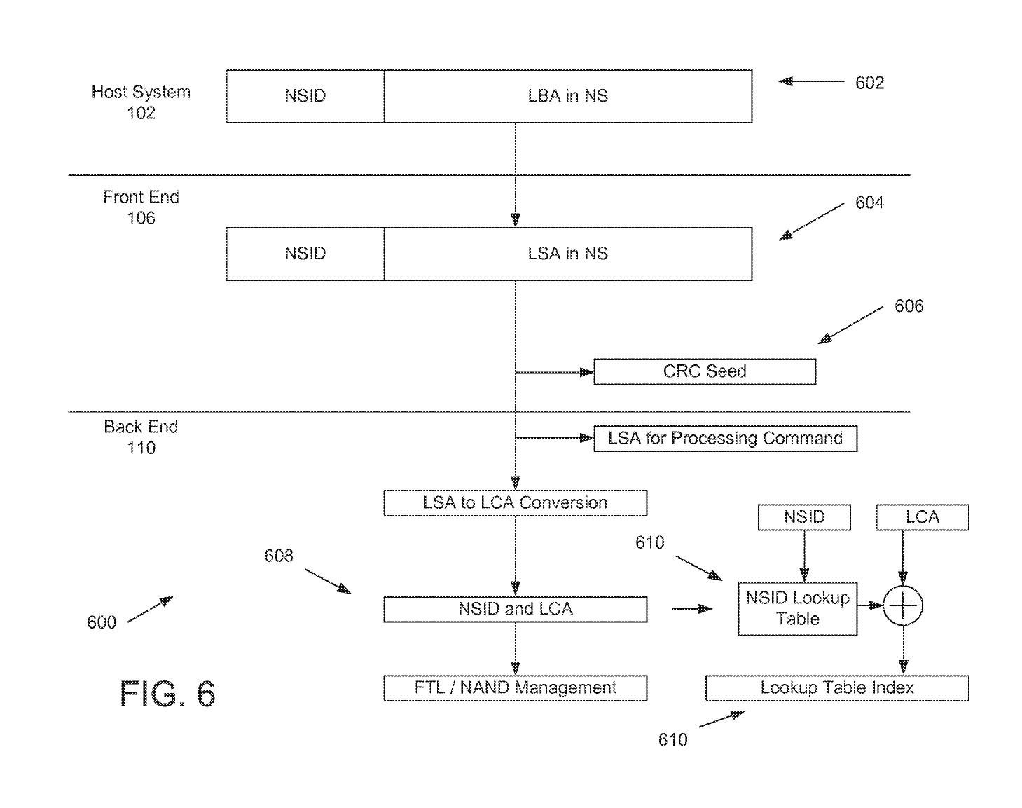

FIG. 6 is a processing flow diagram 600 that shows addresses as manipulated by SSD controller 105, according to an example. The flow in the diagram begins with the host system 102 and ends with the back end 110 of the SSD controller 105. To access (read or write) particular data within storage device 104, host system 102 provides an LBA-based address 602 that includes a namespace identifier (“NSID”) and that specifies a logical block address (“LBA”) within the namespace associated with the NSID. The LBA specifies a particular block within the associated namespace. Note that because namespaces are independent logical subdivisions of storage for storage device 104, an LBA in one namespace points to a different location in NAND 112 than the same LBA in a different namespace.

Front end 106 receives the specified address 602 and associated command (not shown) and buffers these values for further processing. Front end 106 converts the LBA-based address 602 to an address based on sectors (a “logical sector-based address” or “LSA-based address” 604). Sectors are subdivisions of blocks that are managed internally to storage device 104. Host system 102 typically refers to addresses by logical block and not by logical sector, and for internal management, SSD controller 105 converts an LBA-based address to an LSA-based address.

In various embodiments, error correction unit 130 (discussed above with respect to FIG. 1) performs operations associated with cyclic redundancy checks (“CRC”) on data in NAND 112. When data is modified in the NAND 112, front end 106 writes a check sequence to a location within the NAND 112 that corresponds to the modified data. The check sequence is based on the data that is modified as well as on a seed value. By using an address-based seed, the check sequence can protect both the data for which the check sequence is generated and the address at which the data is stored. For example, SSD controller 105 may want to read data stored at one location but instead erroneously reads data stored at a different location. Because the data stored at both locations is protected by check sequences generated based on seeds with values that differ because different addresses are used for generation, error correction unit 130 is correctly able to determine that the data read is erroneous, despite the identical data value.

As discussed above, a namespace-based address, instead of the linear, internal address is used for the CRC seed. More specifically, the CRC seed includes the namespace ID of the namespace in which the accessed data is located. The CRC seed also includes the offset within that namespace that corresponds to the data being accessed. As shown in FIG. 6, the particular offset used for the CRC seed 606 is the logical sector address within the namespace. This namespace-based address, instead of the internal linear address described above is used as the CRC seed because of difficulties associated with resizing namespaces that would exist if the linear, internal address would instead be used for the CRC seed.

More specifically, referring momentarily to FIG. 4, namespaces have associated beginning and end linear internal addresses. For example, namespace 0 has a beginning address of 0x00000000 and an end address of 0x00014FBF. Similarly, namespace 1 has a beginning address of 0x00014FC0 and an end address of 0x00038CC1. When a namespace increases in size, the beginning address of another namespace may change. For example, as shown in FIG. 4, when namespace 0 increases in size, the beginning address corresponding to namespace 1 changes from 0x00014FC0 to 0x0019266. This change in beginning address may cause data stored within namespace 1 to have their associated internal linear addresses changed, which would change the CRC seeds for such data. Because the CRC seeds would change, the CRC check value would have to be recalculated for all data in namespace 1, which would be extremely taxing on SSD controller 105.

For these reasons, as shown in FIG. 6, front end 106 uses the namespace-based address for the CRC seed 606. This namespace-based address includes the namespace ID and the LSA within the namespace. This logical address is namespace size independent because of the fact that addresses within each namespace range from 0 to a maximum value. Unlike with the linear addresses discussed above, resizing a namespace would not affect these namespace-based address values. Thus, using the namespace-based addresses for the CRC seed would allow resizing to occur without requiring that CRC check values be recalculated.

Referring back to FIG. 6 and moving forward in the processing flow diagram 600, back end 110 uses the namespace-based address 604 (the “LSA-based address”) as the address for processing a command. More specifically, when back end 110 receives a command for processing from front end 106, back end 110 accesses data for the command based on the LSA-based address 604. Back end also performs LSA to LCA (“logical cluster address”) conversion to generate a namespace-including logical cluster address 608 (“LCA-based address”). Back end 110 uses this LCA-based address 608 for other operations, including operations associated with flash translation layer functionality, which are performed by logical-to-physical translation unit 132 and by NAND management unit 134. These operations are discussed in further detail below.

When back end 110 needs to obtain a physical address in the NAND 112, back end 110 (specifically, logical-to-physical translation unit 132) converts the LCA-based address 608 to a physical address via a physical-address conversion operation. Although not all operations in back end 110 require a physical address, back end 110 obtains a physical address whenever back end 110 accesses the NAND 112. To perform the logical-to-physical conversion, logical-to-physical translation unit 132 submits the namespace ID to a NSID lookup table 610. The NSID lookup table 610 stores the beginning addresses in the linear internal address space of each namespace. Thus, the result from the NSID lookup table 610 is the beginning address corresponding to the submitted namespace ID. Logical-to-physical translation unit 132 adds the LCA offset of the LCA-based address 608 (that is, the LCA within the namespace identified by the NSID in the LCA-based address 608) to the obtained beginning address to obtain the linear, internal address corresponding to the LCA-based address 608. Logical-to-physical translation unit 132 provides this linear, internal address to a logical-to-physical lookup table, which converts the LCA-based address 608 to a physical address for use in NAND 112.

As described above, the linear, internal address is used for this logical-to-physical lookup table because using a namespace-based address would be cumbersome. On the other hand, a namespace-based address is used for the CRC seed because using a linear, internal address would require frequent recalculation of CRC seeds, which would be cumbersome. In addition, for operations that use a logical address, the FTL functionality of the logical-to-physical translation unit 132 and the functionality of the NAND management unit 134 uses namespace-based addresses rather than the linear, internal addresses. More specifically, some operations related to data stored in NAND 112 can be performed with logical addresses and do not need physical addresses. Using namespace-based addresses for these management tasks saves SSD controller 105 from expending processing resources to convert a namespace-based address to a linear, internal address each time SSD controller 105 performs one of these operations.

One example of FTL and NAND management operations that is performed with namespace-based logical addresses rather than the internal, linear addresses are log block operations. Log block operations are techniques in which, when back end 110 (e.g., logical-to-physical translation unit 132 and/or NAND management unit 134) moves data around in NAND 112 for various reason such as related to wear leveling, garbage collection, or the like, back end 110 does not necessarily immediately reflect this movement in the logical-to-physical mapping table but instead records this movement in log-block data. The log-block data includes the logical address of the data that was moved and also includes a history of which physical addresses that data has been moved between. To prevent the need to perform namespace-based address-to-linear, internal address translation, the logical address included in the log-block mapping data may be a namespace-based address. Other operations may also be handled with namespace-based logical addresses rather than internal, linear addresses. For garbage collection, it is typically advantageous to gather valid data from a single namespace rather than from randomly selected namespaces. Because of the difference in namespace utilization, the lifetime of data in different namespaces may be different. Gathering data that has similar lifetime contributes to the efficiency of garbage collection and to lower write amplification. The lifetime difference of data in different namespaces also helps with efficiency for wear leveling, since

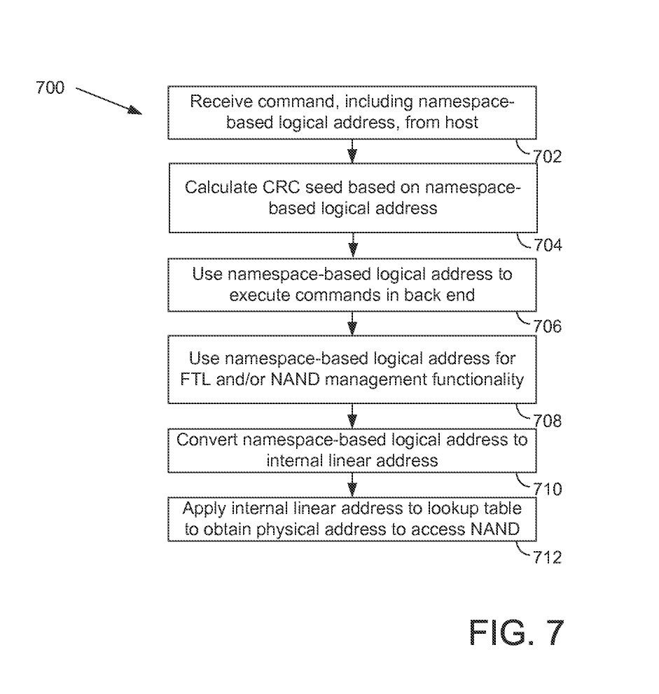

FIG. 7 is a flow diagram of method steps for managing namespace-based logical addresses, according to an example. Although described with respect to the system and related operations described above with respect to FIGS. 1-6, those of skill in the art will understand that any system performing the steps described herein, in technically feasible alternative orders, falls within the scope of this disclosure.

As shown, a method 700 begins at step 702, in which SSD controller 105 receives a command that includes a namespace-based logical address from host system 102. The namespace-based logical address includes a namespace identifier that identifies a namespace and an offset that specifies a location within the namespace. As described above, logical addresses within each namespace begin at 0 and continue linearly to a maximum value. The offset specifies a particular location within this range of logical addresses. At step 704, SSD controller 105 calculates a CRC seed based on the namespace-based logical address. The CRC seed may simply be the namespace-based logical address itself. This CRC seed is subsequently used to calculate a CRC check sequence for data associated with the namespace-based logical address. The namespace-based logical address is used for the CRC seed because the value of this address is not dependent on the size of the namespace. This means that namespaces can be resized without requiring a recalculation of CRC check sequences.

At step 706, back end 110 uses the namespace-based logical address to execute commands. Commands that may be executed by back end 110, after receiving the commands from front end, include commands to read or write values to the NAND 112. Although the namespace-based logical address may eventually be converted to a different type of address (e.g., linear address or physical address), when executed, the namespace-based logical address is the address that is used to indicate the data for which the command executes.

At step 708, back end 110 uses the namespace-based logical address for FTL and/or NAND management functionality. This functionality includes functionality associated with log blocks, which record migrations of data between different physical locations in the NAND 112, for wear leveling, garbage collection, and other related functionality. For these operations, the namespace-based logical address is used when a logical address, rather than a physical address, is used. Namespace-based logical addresses are used because doing so allows backend 110 to forego operations associated with converting the namespace-based logical address to a linear address.

At step 710, in order to access physical locations in the NAND 112, back end 110 converts the namespace-based logical address to an internal linear address for use as an index to a logical-to-physical address translation table. At step 712, back end 110 applies the linear address to a lookup table to obtain a physical address to access NAND.

It is important to note that not all commands received from host system 102 will result in an access to a location within NAND 112, but instead may result only in modifications to data that are descriptive of logical addresses associated with those particular locations in NAND 112. In one example, erasing data may access and modify only a table that indicates which parts of memory contain valid (unerased) data and thus would not have to directly access the portion of the NAND 112 corresponding to the data to be erased. For these reasons, step 712 is not performed for all commands received from host system 102.

In sum, embodiments described herein provide techniques for efficient CRC checking, while also providing address-line protection, and while allowing for efficient namespace resizing and flash transfer layer operations. The techniques include obtaining a namespace-based logical address from a host system and using that namespace-based logical address as a CRC seed for data stored in a NAND. The techniques also include utilizing the namespace-based logical address for the flash transfer layer operations. The techniques further include converting the namespace-based logical address to a linear, “internal” address when determination of a physical address is required. This internal address is provided to a logical-to-physical address lookup table in order to obtain the physical address. Advantageously, using an address-based CRC seed allows for CRC operations to determine when an access is using an erroneous address. Additionally, using a namespace-based logical address allows for namespace resizing to occur without affecting the CRC seed. Because recalculating the CRC seed is a costly operation, preventing such an operation from occurring reduces the amount of computing work required to be performed. Using the namespace-based logical address for FTL operations allows some such operations to be conducted without converting the namespace-based address to a linear address, which may be a costly operation. Thus, the amount of processing that is performed may be reduced.

The various embodiments described herein may employ various computer-implemented operations involving data stored in computer systems. For example, these operations may require physical manipulation of physical quantities—usually, though not necessarily, these quantities may take the form of electrical or magnetic signals, where they or representations of them are capable of being stored, transferred, combined, compared, or otherwise manipulated. Further, such manipulations are often referred to in terms, such as producing, identifying, determining, or comparing. Any operations described herein that form part of one or more embodiments of the invention may be useful machine operations. In addition, one or more embodiments of the invention also relate to a device or an apparatus for performing these operations. The apparatus may be specially constructed for specific required purposes, or it may be a general purpose computer selectively activated or configured by a computer program stored in the computer. In particular, various general purpose machines may be used with computer programs written in accordance with the teachings herein, or it may be more convenient to construct a more specialized apparatus to perform the required operations.

The various embodiments described herein may be practiced with other computer system configurations including hand-held devices, microprocessor systems, microprocessor-based or programmable consumer electronics, minicomputers, mainframe computers, and the like.

One or more embodiments of the present invention may be implemented as one or more computer programs or as one or more computer program modules embodied in one or more computer readable media. The term computer readable medium refers to any data storage device that can store data which can thereafter be input to a computer system—computer readable media may be based on any existing or subsequently developed technology for embodying computer programs in a manner that enables them to be read by a computer. Examples of a computer readable medium include a hard drive, network attached storage (NAS), read-only memory, random-access memory (e.g., a flash memory device), a CD (Compact Discs)—CD-ROM, a CD-R, or a CD-RW, a DVD (Digital Versatile Disc), a magnetic tape, and other optical and non-optical data storage devices. The computer readable medium can also be distributed over a network coupled computer system so that the computer readable code is stored and executed in a distributed fashion.

Boundaries between various components, operations and data stores are somewhat arbitrary, and particular operations are illustrated in the context of specific illustrative configurations. Other allocations of functionality are envisioned and may fall within the scope of the invention(s). In general, structures and functionality presented as separate components in exemplary configurations may be implemented as a combined structure or component. Similarly, structures and functionality presented as a single component may be implemented as separate components. These and other variations, modifications, additions, and improvements may fall within the scope of the appended claim(s).

Although one or more embodiments of the present invention have been described in some detail for clarity of understanding, it will be apparent that certain changes and modifications may be made within the scope of the claims. Accordingly, the described embodiments are to be considered as illustrative and not restrictive, and the scope of the claims is not to be limited to details given herein, but may be modified within the scope and equivalents of the claims. In the claims, elements and/or steps do not imply any particular order of operation, unless explicitly stated in the claims.

We claim:

1. A data storage device comprising:
a non-volatile semiconductor storage device; and
a controller configured to:
determine an error-correction seed for data for the non-volatile semiconductor storage device based on a first logical address associated with the data that includes a first namespace identifier and a first logical block address,
convert the first logical address to an internal linear address that does not include the first namespace identifier,
determine a physical address based on the internal linear address, and
access data stored in the non-volatile semiconductor storage device based on the physical address.

2. The data storage device of claim 1, wherein:
the error-correction seed comprises a cyclic redundancy check seed; and
the controller is further configured to perform cyclic redundancy check operations on data stored in the flash memory device.

3. The data storage device of claim 1, wherein:
the controller is configured to convert the first logical address to the internal linear address by converting the first namespace identifier to an internal linear base address based on a namespace identifier lookup table and to add the first logical block address to the internal linear base address to obtain the internal linear address.

4. The data storage device of claim 1, wherein the controller is further configured to:
perform one or more flash translation layer operations with the first logical address.

5. The data storage device of claim 4, wherein the one or more flash translation layer operations comprises a log block operation.

6. The data storage device of claim 1, wherein the controller is configured to determine the physical address based on a logical address to physical address conversion table.

7. The data storage device of claim 1, wherein:
the first logical block address indicates a location of a block in a logical address space; and
the internal logical address indicates a location of a sector in an internal logical address space.

8. The data storage device of claim 1, wherein:
the first namespace identifier is associated with a first namespace that spans a first range within an internal logical address space associated with the internal logical address, and
a second range within the internal logical address space is associated with a second namespace.

9. The data storage device of claim 8, wherein the controller is further configured to:
resize the first namespace by adjusting an end address in the internal logical address space associated with the first namespace and by adjusting a beginning address in the internal logical address space associated with the second namespace.

10. A method, comprising:
determining an error-correction seed for data for a non-volatile semiconductor storage device based on a first logical address associated with the data that includes a first namespace identifier and a first logical block address,
converting the first logical address to an internal linear address that does not include the first namespace identifier,
determining a physical address based on the internal linear address, and
accessing data stored in the non-volatile semiconductor storage device based on the physical address.

11. The method of claim 10, wherein:
the error-correction seed comprises a cyclic redundancy check seed; and
the method further comprises performing cyclic redundancy check operations on data stored in the flash memory device.

12. The method storage device of claim 10, wherein converting the first logical address to the internal linear address comprises:
converting the first namespace identifier to an internal linear base address based on a namespace identifier lookup table; and
adding the first logical block address to the internal linear base address to obtain the internal linear address.

13. The method of claim 10, further comprising:
performing one or more flash translation layer operations with the first logical address.

14. The method of claim 13, wherein the one or more flash translation layer operations comprises a log block operation.

15. The method of claim 10, further comprising:
determining the physical address based on a logical address to physical address conversion table.

16. The method of claim 10, wherein:
the first logical block address indicates a location of a block in a logical address space; and
the internal linear address indicates a location of a sector in an internal linear address space.

17. The method of claim 10, wherein:
the first namespace identifier is associated with a first namespace that spans a first range within an internal linear address space associated with the internal linear address, and
a second range within the internal linear address space is associated with a second namespace.

18. The method of claim 17, further comprising:
resizing the first namespace by adjusting an end address in the internal linear address space associated with the first namespace and by adjusting a beginning address in the internal logical address space associated with the second namespace.

19. A non-transitory computer-readable medium storing instructions that, when executed by a processor, cause the processor to perform a method comprising:
determining an error-correction seed for data for a non-volatile semiconductor storage device based on a first logical address associated with the data that includes a first namespace identifier and a first logical block address,
converting the first logical address to an internal linear address that does not include the first namespace identifier,
determining a physical address based on the internal linear address, and
accessing data stored in the non-volatile semiconductor storage device based on the physical address.

20. The non-transitory computer-readable medium of claim 19, wherein:
the error-correction seed comprises a cyclic redundancy check seed; and
the method further comprises performing cyclic redundancy check operations on data stored in the flash memory device.
